(19) United States
(12) Patent Application Publication
(10) Pub. No.: US 2023/0209855 A1
(43) Pub. Date: Jun. 29, 2023

(54) LIGHT-EMITTING DEVICE, LIGHT-EMITTING SUBSTRATE AND LIGHT-EMITTING APPARATUS

(71) Applicant: BOE TECHNOLOGY GROUP CO., LTD., Beijing (CN)

(72) Inventors: Yang LIU, Beijing (CN); Xueqin CHEN, Beijing (CN); Lixia QIU, Beijing (CN)

(73) Assignee: BOE TECHNOLOGY GROUP CO., LTD., Beijing (CN)

(21) Appl. No.: 17/927,954

(22) PCT Filed: Oct. 25, 2021
(86) PCT No.: PCT/CN2021/126196

§ 371 Date: Nov. 28, 2022

(30) Foreign Application Priority Data
Mar. 25, 2021 (CN) 202110322403.8

(51) Int. Cl. H10K 50/12; H10K 85/60

(52) U.S. Cl. CPC H10K 50/121; H10K 85/626; H10K 85/633; H10K 85/636; H10K 85/6574; H10K 2101/25

(57) ABSTRACT

A light-emitting device includes a light-emitting layer. The light-emitting layer includes a host material. The host material includes a p-type material and an n-type material. The p-type material and the n-type material are configured to form an exciplex. An absolute value of a difference between a wavelength corresponding to a peak of a normalized fluorescence emission spectrum of the exciplex and a wavelength corresponding to a peak of a normalized fluorescence emission spectrum of the n-type material being less than or equal to 5 nm.

### CROSS-REFERENCE TO RELATED APPLICATIONS

This application is a national phase entry under 35 USC 371 of International Patent Application No. PCT/CN2021/126196 filed on Oct. 25, 2021, which claims priority to Chinese Patent Application No. 202110322403.8, filed on Mar. 25, 2021, which are incorporated herein by reference in their entirety.

### TECHNICAL FIELD

Embodiments of the present disclosure relate to the fields of illumination and display, and in particular, to a light-emitting device, a light-emitting substrate and a light-emitting apparatus.

### BACKGROUND

Organic light-emitting diode (OLED) panels, which have characteristics such as self-luminescence, high contrast ratio, small thickness, light weight, quick response, wide viewing angle, low power consumption, wide applicable temperature range, low cost and simple manufacturing process, are getting more and more widely used in recent years.

### SUMMARY

In an aspect, a light-emitting device is provided. The light-emitting device includes a light-emitting layer. The light-emitting layer includes a host material. The host material includes a p-type material and an n-type material. The p-type material and the n-type material are configured to form an exciplex, and an absolute value of a difference between a wavelength corresponding to a peak of a normalized fluorescence emission spectrum of the exciplex and a wavelength corresponding to a peak of a normalized fluorescence emission spectrum of the n-type material is less than or equal to 5 nm.

In some embodiments, a difference between an energy of singlet excitons of the exciplex and an energy of triplet excitons of the exciplex is less than or equal to 0.3 eV.

In some embodiments, a ratio of a hole mobility of the p-type material to an electron mobility of the n-type material is greater than or equal to 1:100, and less than or equal to 100:1.

In some embodiments, the ratio of the hole mobility of the p-type material to the electron mobility of the n-type material is 1:100, 50:50 or 100:1.

In some embodiments, the hole mobility of the p-type material is greater than or equal to 1×10⁻⁸ cm²/(V·s), and less than or equal to 1×10⁻⁴ cm²/(V·s). The electron mobility of the n-type material is greater than or equal to 1×10⁻⁸ cm²/(V·s), and less than or equal to 1×10⁻⁴ cm²/(V·s).

In some embodiments, the wavelength corresponding to the peak of the normalized fluorescence emission spectrum of the n-type material is greater than or equal to 430 nm, and less than or equal to 470 nm.

In some embodiments, a wavelength corresponding to a peak of a normalized fluorescence emission spectrum of the p-type material is greater than or equal to 380 nm, and less than or equal to 430 nm.

In some embodiments, an absolute value of an energy of a lowest unoccupied molecular orbital of the n-type material is greater than or equal to 2.6 eV, and less than or equal to 3.0 eV; and an absolute value of an energy of a highest occupied molecular orbital of the n-type material is greater than or equal to 5.5 eV, and less than or equal to 6.1 eV.

In some embodiments, an absolute value of an energy of a highest occupied molecular orbital of the p-type material is greater than or equal to 5.4 eV, and less than or equal to 5.9 eV; and an absolute value of an energy of a lowest unoccupied molecular orbital of the p-type material is greater than or equal to 2.3 eV, and less than or equal to 2.8 eV.

In some embodiments, a mole ratio of the p-type material to the n-type material is greater than or equal to 2:8, and less than or equal to 8:2.

In some embodiments, the mole ratio of the p-type material to the n-type material is 2:8, 5:4 or 8:2.

In some embodiments, the n-type material is selected from anthracene compounds.

In some embodiments, a general formula of the anthracene compounds is:

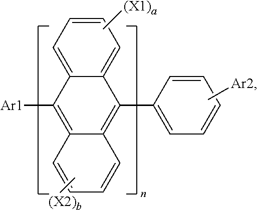

where Ar1 represents any one of phenyl group, naphthyl group and biphenyl group; Ar2 represents any one of phenyl group, 1-naphthyl group, 2-naphthyl group, 2-biphenyl group, 3-biphenyl group and 4-biphenyl group; X1 and X2 each independently represent any one of an aryl group having 6 to 50 ring carbon atoms, an aromatic heterocyclic group having 5 to 50 ring atoms, an alkyl group having 1 to 50 carbon atoms, an alkoxy group having 1 to 50 carbon atoms, an aralkyl group having 6 to 50 carbon atoms, an aryloxy group having 5 to 50 ring atoms, an arylthio group having 5 to 50 ring atoms, an alkoxycarbonyl group having 1 to 50 carbon atoms, a carboxyl group, halogen, a cyano group, a nitro group and a hydroxyl group; a value of n is any one of 1, 2 and 3; and values of a and b are each independently any one of 0, 1, 2 and 3.

In some embodiments, the p-type material is selected from aromatic amine compounds.

In some embodiments, a general formula of the aromatic amine compounds is:

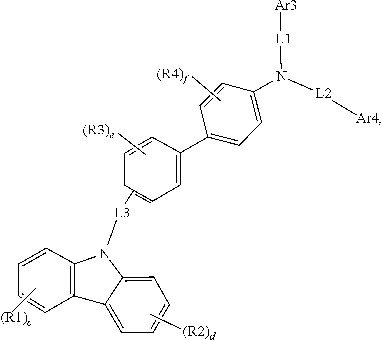

where L1 to L3 each independently represent a direct bonding, or a substituted or unsubstituted arylene group with 6 to 60 carbon atoms; Ar3 and Ar4 each independently represent any one of hydrogen, deuterium, halogen, a cyano group, a nitro group, a substituted or unsubstituted silyl group, a substituted or unsubstituted alkyl group, a substituted or unsubstituted cycloalkyl, substituted or unsubstituted aryl group having 6 to 60 carbon atoms, and a substituted or unsubstituted heterocyclic group having 2 to 60 carbon atoms; R1 to R4 each independently represent any one of hydrogen, deuterium, halogen, a cyano group, a nitro group, a substituted or unsubstituted alkyl group having 1 to 60 carbon atoms, a substituted or unsubstituted haloalkyl group with 1 to 60 carbon atoms, a substituted or unsubstituted haloalkoxy group with 1 to 60 carbon atoms, a substituted or unsubstituted cycloalkyl group with 3 to 60 carbon atoms, a substituted or unsubstituted alkenyl group having 2 to 60 carbon atoms, a substituted or unsubstituted aryl group having 6 to 60 carbon atoms, and a substituted or unsubstituted heterocyclic group having 2 to 60 carbon atoms; and values of c, d, e and f are independently any one of 0, 1, 2 and 3.

In some embodiments, the light-emitting device further includes a first electrode and a second electrode that are disposed opposite to each other. The light-emitting layer is located between the first electrode and the second electrode.

In some embodiments, the light-emitting device further includes a hole injection layer, a hole transport layer, an electron blocking layer, a hole blocking layer, an electron transport layer and an electron injection layer. The hole injection layer, the hole transport layer and the electron blocking layer are located between the first electrode and the light-emitting layer; and the hole blocking layer, the electron transport layer and the electron injection layer are located between the light-emitting layer and the second electrode.

In another aspect, a light-emitting substrate is provided. The light-emitting substrate includes a base substrate and a plurality of light-emitting devices disposed on the base substrate. At least one of the plurality of light-emitting devices is the above-mentioned light-emitting device described above.

In yet another aspect, a light-emitting apparatus includes the light-emitting substrate described above.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person having ordinary skill in the art can obtain other drawings according to these accompanying drawings. In addition, the accompanying drawings in the following description may be regarded as schematic diagrams, and are not limitations to actual sizes of products, actual processes of methods or actual timings of signals to which the embodiments of the present disclosure relate.

FIG. 1 is a plan view of a light-emitting substrate, in accordance with some embodiments;

FIG. 2 is a section of the light-emitting substrate shown in FIG. 1 taken along the direction O-O′;

FIG. 3 is a section of a light-emitting device, in accordance with some embodiments;

FIG. 4 is a section of another light-emitting device, in accordance with some embodiments;

FIG. 5 shows normalized fluorescence spectra of light-emitting devices, in accordance with some embodiments;

FIG. 6 shows normalized fluorescence spectra of some other light-emitting devices, in accordance with some embodiments;

FIG. 7 shows normalized fluorescence spectra of yet some other light-emitting devices, in accordance with some embodiments;

FIG. 8 is a diagram showing distribution curves of fluorescence spectral intensity versus distance for light-emitting devices, in accordance with some embodiments; and

FIG. 9 is a diagram showing distribution curves of fluorescence spectral intensity versus distance for some other light-emitting devices, in accordance with some embodiments.

### DETAILED DESCRIPTION

Technical solutions in some embodiments of the present disclosure will be described clearly and completely below with reference to the accompanying drawings. However, the described embodiments are merely some but not all embodiments of the present disclosure. All other embodiments obtained by a person of ordinary skill in the art based on embodiments in the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representation of the above terms does not necessarily refer to the same embodiment(s) or example(s). In addition, the specific features, structures, materials or characteristics may be included in any one or more embodiments or examples in any suitable manner.

In the description of the present disclosure, it will be understood that orientations or positional relationships indicated by terms “center”, “upper”, “lower”, “front”, “back”, “left”, “right”, “vertical”, “horizontal”, “top”, “bottom”, “inner”, “outer”, etc. are based on orientations or positional relationships shown in the accompanying drawings, which are merely to facilitate and simplify the description of the present disclosure, but not to indicate or imply that the referred devices or elements must have a particular orientation, or must be constructed and operated in a particular orientation. Therefore, they should not be construed as limitations to the present disclosure.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/the plurality of” means two or more unless otherwise specified.

In the description of the embodiments of the present disclosure, it will be noted that, unless otherwise explicitly defined or limited, the term “connected” or “connection” shall be understood in a broad sense. For example, it may be a fixed connection, a detachable connection or an integral connection; it may be a mechanical connection or an electrical connection; it may be directly connected or indirectly connected through an intermediate medium; or it may be internal connection of two elements or interaction of two elements. Specific meanings of the above terms in the present disclosure shall be understood by a person skilled in the art on a case-by-case basis.

Terms such as “about”, “substantially” or “approximately” as used herein include a stated value and an average value within an acceptable range of deviation of a particular value. The acceptable range of deviation is determined by a person of ordinary skill in the art in view of the measurement in question and the error associated with the measurement of a particular quantity (i.e., the limitations of the measurement system).

Embodiments of the present disclosure provide a light-emitting apparatus. The light-emitting apparatus is, for example, an organic light-emitting diode (OLED) apparatus, and may be configured to illuminate or display images. In a case where the light-emitting apparatus is configured to illuminate, the light-emitting apparatus is, for example, a lamp used for illumination or various signal lamps. In a case where the light-emitting apparatus is configured to display images, the light-emitting apparatus may be of various product forms. For example, the light-emitting apparatus may be specifically any product or component having display functions such as electronic paper, a television, a monitor, a notebook computer, a tablet computer, a digital photo frame, a mobile phone or a navigator.

The light-emitting apparatus provided in embodiments of the present disclosure includes a light-emitting substrate. It will be understood that, in a case where the light-emitting apparatus is an OLED apparatus, the light-emitting substrate is an OLED substrate.

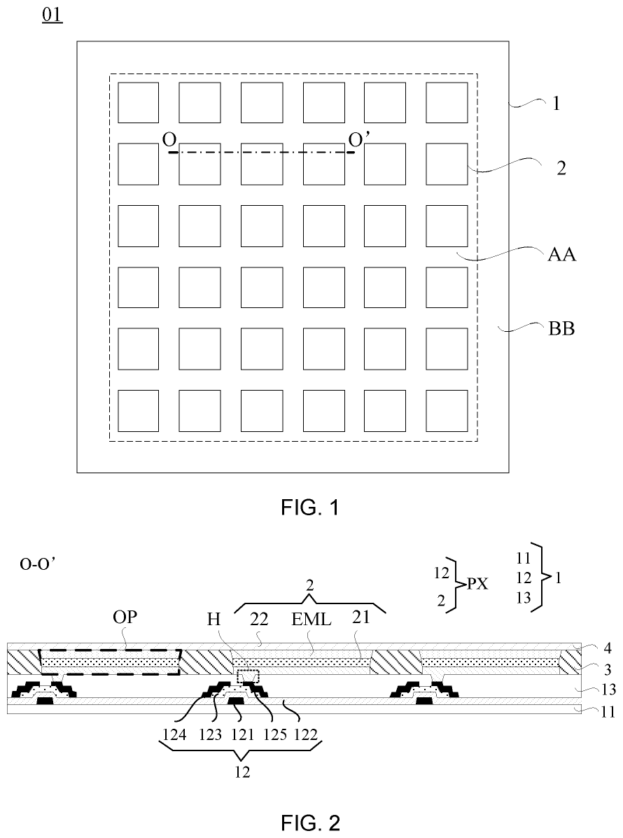

With reference to FIGS. 1 to 2, a light-emitting substrate 01 provided in embodiments of the present disclosure includes a base substrate 1 and a plurality of light-emitting devices 2 disposed on the base substrate 1.

Here, the base substrate 1 refers to a component for carrying the plurality of light-emitting devices 2, and a specific structure of the base substrate 1 may vary.

In some examples, the base substrate 1 is a base without any other structures. For example, the base substrate 1 may be a rigid base such as a glass base or a sapphire base. For another example, the base substrate 1 may be a flexible base such as a polyethylene terephthalate (PET) base, a polyethylene naphthalate two formic acid glycol ester (PEN) base or a polyimide (PI) base.

In some other examples, the base substrate 1 may be a base with pixel driving circuits and/or a driving integrated circuit (IC) formed thereon.

For example, with continued reference to FIG. 2, the base substrate 1 includes a base 11, and pixel driving circuits and a planarization layer 13 which are formed on a side of the base 11. The planarization layer 13 is located on a side of the pixel driving circuits facing away from the base 11.

The pixel driving circuit may include at least two transistors 12 (FIG. 2 shows only one of transistors in each of pixel driving circuits for illustration). Each transistor 12 may include a gate 121, a portion of a gate insulating layer 122, an active layer 123, a source 124 and a drain 125. Depending on a relative positional relationship between the gate 121 and the active layer 123, the transistor 12 may be a top-gate thin film transistor, a bottom-gate thin film transistor or a double-gate thin film transistor, which is not specifically limited here. For example, the transistor 12 is a bottom-gate transistor. The gate 121 is located on a side of the active layer 123 proximate to the base 11. The portion of the gate insulating layer 122 is provided between the gate 121 and the active layer 123. The source 124 and the drain 125 are located on a side of the active layer 123 away from the base 11, and are both connected to the active layer 123. The drain 125 is further electrically connected to a light-emitting device 2.

The light-emitting device 2 may be formed on a side of the planarization layer 13 away from the pixel driving circuit, and be electrically connected to the pixel driving circuit through a via hole H provided in the planarization layer 13.

For example, the light-emitting substrate 01 further includes a pixel defining layer 3 disposed on a side of the planarization layer 13 facing away from the base 11. The pixel defining layer 3 has opening regions OP. Each light-emitting device 2 is formed in a respective opening region OP.

The light-emitting substrate 01 may further include an encapsulation layer 4 disposed on a side of the light-emitting devices 2 facing away from the base 11.

With reference to FIG. 1, the light-emitting substrate 01 has a light-emitting region AA and a peripheral region BB located on at least one side of the light-emitting region AA. The pixel driving circuits and the light-emitting devices 2 may all be located in the light-emitting region AA. Each light-emitting device 2 is electrically connected to a respective pixel driving circuit, so that the two form a sub-pixel PX. A plurality of sub-pixels PX may be arranged in an array in the light-emitting region AA.

Depending on that colors of light emitted by the light-emitting devices 2 are same or different, the light-emitting substrate 01 may emit light of a single color or light with adjustable color.

In some embodiments, the light-emitting devices 2 emit light of a same color. For example, the light-emitting devices 2 all emit red light. In this case, the light-emitting substrate 01 may emit red light, and the light-emitting substrate 01 may be a substrate for illumination.

In some embodiments, the light-emitting devices 2 emit light of different colors. For example, the plurality of light-emitting devices 2 may include light-emitting devices 2 for emitting red light, light-emitting devices 2 for emitting blue light and light-emitting devices 2 for emitting green light. In this case, there may be two situations. In a first situation, light-emitting devices 2 with one color may be selected to be controlled to emit light, and light-emitting devices 2 with the other two colors may be controlled not to emit light, so that the light-emitting substrate 01 emit light of a single color. In this case, the light-emitting substrate 01 may be used for illumination. In a second situation, the light-emitting devices 2 emitting light of different colors may be controlled to emit light according to a preset timing sequence, so that multi-colored light may be emitted. In this case, the light-emitting substrate 01 may be used for illumination or display images.

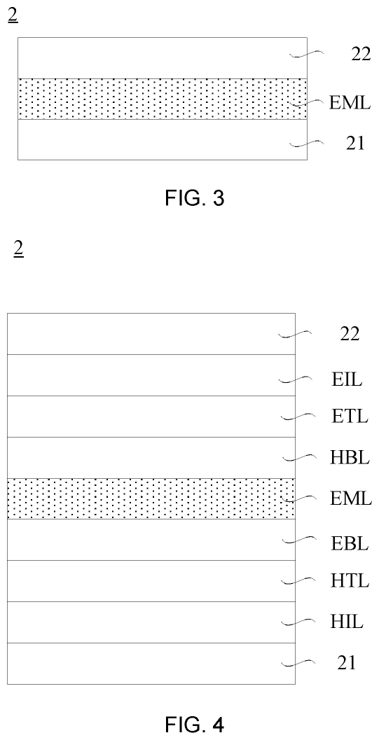

Embodiments of the present disclosure provide a light-emitting device 2. With reference to FIG. 3, the light-emitting device 2 includes a first electrode 21 and a second electrode 22 that are disposed opposite to each other, and a light-emitting layer EML located between the first electrode 21 and the second electrode 22. For example, the first electrode 21 may be an anode, and the second electrode 22 may be a cathode. For another example, the first electrode 21 may be a cathode, and the second electrode 22 may be an anode.

In the following embodiments, the description is made by taking an example where the first electrode 21 is an anode and the second electrode 22 is a cathode.

In some embodiments, with reference to FIG. 4, in addition to the first electrode 21, the second electrode 22 and the light-emitting layer EML, the light-emitting device 2 may further include at least one of a hole injection layer HIL, a hole transport layer HTL, an electron blocking layer EBL, a hole blocking layer HBL, an electron transport layer ETL and an electron injection layer EIL.

In a case where the light-emitting device 2 includes the hole injection layer HIL, the hole transport layer HTL, the electron blocking layer EBL, the hole blocking layer HBL, the electron transport layer ETL and the electron injection layer EIL, the hole injection layer HIL, the hole transport layer HTL and the electron blocking layer EBL are located between the first electrode 21 and the light-emitting layer EML, and the hole blocking layer HBL, the electron transport layer ETL and the electron injection layer EIL are located between the light-emitting layer EML and the second electrode 22.

In this way, due to an action of an applied electric field, holes from the first electrode 21 and electrons from the second electrode 22 both move towards the light-emitting layer EML, and combine with each other in the light-emitting layer EML to release energy, so that light is emitted.

In some embodiments, the light-emitting layer EML includes a host material and a guest material. The host material includes an n-type material and a p-type material, and the p-type material and the n-type material can form an exciplex. An absolute value of a difference between a wavelength corresponding to a peak of a normalized fluorescence emission spectrum of the exciplex and a wavelength corresponding to a peak of a normalized fluorescence emission spectrum of the n-type material is less than or equal to 5 nm.

The exciplex is an aggregate of molecules the n-type material and the p-type material, and the emission spectrum of the exciplex is different from the emission spectrum of the n-type material and an emission spectrum of the p-type material. The exciplex may form a new band gap. The p-type material may be regarded as an electron donor material, and the n-type material may be regarded as an electron acceptor material. For example, a blend film of the p-type material and the n-type material may form the exciplex under photoexcitation conditions or electroexcitation conditions. In this case, an excited state of the electron acceptor material and a ground state of the electron donor material interact with each other to generate charge transfer luminescence. Thus, light is emitted, which is in a new spectrum that is different from the emission spectrum of the p-type material and the emission spectrum of the n-type material.

The fluorescence emission spectrum refers to a spectrum showing intensities or energy distribution of light of different wavelengths emitted by a luminescent material (e.g., the host material) under an excitation of light of a specific wavelength. In addition, a fluorescence absorption spectrum refers to a spectrum showing intensities or energy distribution of light of different wavelengths absorbed by a luminescent material (e.g., the guest material) under an excitation of light of a specific wavelength. Here, the fluorescence emission spectrum and the fluorescence absorption spectrum may be obtained by testing with a fluorescence spectrometer through a solution method.

A fluorescence emission spectrum of the host material and an absorption spectrum of the guest material are normalized. That is, a total light intensity is set to a unity, so that light intensities on an ordinate all become decimals. In this way, the normalized fluorescence emission spectrum of the host material and the normalized absorption spectrum of the guest material may be obtained. Similarly, by normalizing a fluorescence emission spectrum of the exciplex and a fluorescence emission spectrum of the n-type material, the normalized fluorescence emission spectrum of the exciplex and the normalized fluorescence spectrum of the n-type material may be obtained.

According to Forster energy transfer, for two different fluorescent groups, in a case where a fluorescence emission spectrum of one fluorescent group (a donor) overlaps with an absorption spectrum of the other fluorescent group (an acceptor) to a certain extent, and the two fluorescent groups has an appropriate distance (generally less than 100 Å) therebetween, a phenomenon by which fluorescence energy transfer from the donor to the acceptor may be observed. That is, excitation light of the donor is used for excitation. Compared with a case where the donor exists alone, an intensity of fluorescence generated by the donor is smaller, while an intensity of fluorescence emitted by the acceptor is greatly increased, which is accompanied by a corresponding shortening and lengthening of fluorescence lifetimes thereof. That is to say, the fluorescence emission spectrum of the host material may serve as an excitation spectrum for light emission of the guest material, and part or all of energy of the light is transferred to the guest material, so that the guest material is excited, thereby realizing light emission. In this process, the larger an overlapping area of the fluorescence emission spectrum of the host material and the absorption spectrum of the guest material is, the more sufficiently the energy transfer is performed.

The absolute value of the difference between the wavelength corresponding to the peak of the normalized fluorescence emission spectrum of the exciplex and the wavelength corresponding to the peak of the normalized fluorescence emission spectrum of the n-type material is less than or equal to 5 nm, it will be seen that, in a case where the normalized fluorescence emission spectrum of the n-type material overlaps with the normalized absorption spectrum of the guest material to a great extent, the normalized fluorescence emission spectrum of the exciplex also overlaps with the normalized absorption spectrum of the guest material to a great extent. Therefore, it may be possible to make the Forster energy transfer between the exciplex and the guest material performed as sufficiently as possible.

Compared with the related art where a host material of a light-emitting layer is a single host material such as an n-type material, the light-emitting layer EML in the light-emitting device 2 provided in embodiments of the present disclosure further includes the p-type material, and the p-type material and the n-type material form a double host material. In this way, in an aspect, it may be possible to adjust an region where holes and electrons in the light-emitting device 2 combine with each other by matching the p-type material and the n-type material in an appropriate manner, e.g., by adjusting a hole mobility of the p-type material and an electron mobility of the n-type material; and in another aspect, since the p-type material and the n-type material form the exciplex, it may be possible to make the Forster energy transfer between the host material and the guest material performed as sufficiently as possible. Moreover, in a case where the exciplex has an small energy difference between singlet excitons and triplet excitons thereof, the triplet excitons may be converted into singlet excitons through reverse intersystem crossing (RISC, i.e., a process that the triplet excitons are converted into the singlet excitons under an assistance of ambient heat), which realizes an utilization of the triplet excitons and improves a utilization rate of excitons.

In addition, since the host material of the light-emitting layer in the related art is the single host material such as the n-type material, and an electron mobility of the light-emitting device is higher than a hole mobility thereof, an exciton recombination region of the light-emitting device is proximate to an electron blocking layer. This causes that triplet excitons in the host material in this region gather at an interface between the electron blocking layer and the light-emitting layer, which is prone to triplet-triplet exciton annihilation. In contrast to this, by adding the p-type material, for the host material of the light-emitting layer EML in the embodiments of the present disclosure, not only may a position of an exciton recombination region (i.e., the region where the holes and the electrodes combine with each other) be adjusted, for example, to a middle region of the light-emitting layer EML, but also the utilization rate of the triplet excitons may be improved, which in turn avoids the triplet-triplet exciton annihilation.

In some embodiments, a difference ΔEst between an energy of singlet excitons of the exciplex and an energy of triplet excitons of the exciplex is less than or equal to 0.3 eV. In a case where this condition is met, the triplet excitons in the exciplex are easily converted into singlet excitons through RISC, and then energy of the singlet excitons is transferred to the guest material to emit light, which is beneficial to further improve the utilization rate of the triplet excitons.

In some embodiments, the n-type material is selected from anthracene compounds. For example, a general formula of the anthracene compounds is:

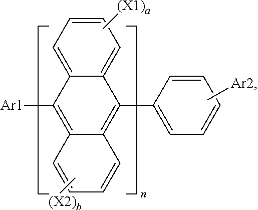

where Ar1 represents any one of phenyl group, naphthyl group and biphenyl group; Ar2 represents any one of phenyl group, 1-naphthyl group, 2-naphthyl group, 2-biphenyl group, 3-biphenyl group and 4-biphenyl group; X1 and X2 each independently represent any one of an aryl group having 6 to 50 ring carbon atoms, an aromatic heterocyclic group having 5 to 50 ring atoms, an alkyl group having 1 to 50 carbon atoms, an alkoxy group having 1 to 50 carbon atoms, an aralkyl group having 6 to 50 carbon atoms, an aryloxy group having 5 to 50 ring atoms, an arylthio group having 5 to 50 ring atoms, an alkoxycarbonyl group having 1 to 50 carbon atoms, a carboxyl group, halogen, a cyano group, a nitryl group and a hydroxyl group; a value of n is any one of 1, 2 and 3; and values of a and b each are independently any one of 0, 1, 2 and 3.

Those skilled in the art will understand that, Ar1, Ar2 and X each independently represent a group; and n, a and b each independently represent a number of respective groups. For example, in a case where n is equal to 1 (n=1), it represents that a number of the following group in the anthracene compounds is 1, where the following group is:

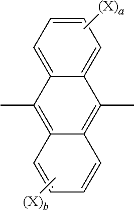

For another example, in a case where a is equal to 0 (a=0), it represents that, a number of the group X1 in the anthracene compounds is 0. That is, the anthracene compounds do not include the group X1. For yet another example, in a case where b is equal to 3 (b=3), it represents that, a number of the group X2 in the anthracene compounds is 3.

In some embodiments, the p-type material is selected from aromatic amine compounds.

For example, a general formula of the aromatic amine compounds is:

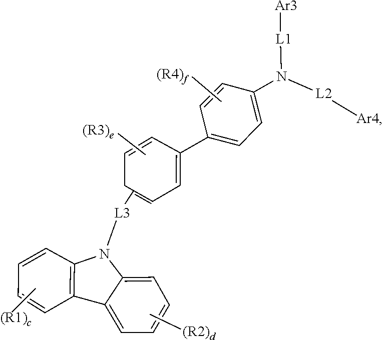

where L1 to L3 each independently represent a direct bonding, or a substituted or unsubstituted arylene group with 6 to 60 carbon atoms; Ar3 and Ar4 each independently represent any one of hydrogen, deuterium, a halogen group, a cyano group, a nitro group, a substituted or unsubstituted silyl group, a substituted or unsubstituted alkyl group, a substituted or unsubstituted cycloalkyl group, a substituted or unsubstituted aryl group having 6 to 60 carbon atoms, and a substituted or unsubstituted heterocyclic group having 2 to 60 carbon atoms; R1 to R4 each independently represent any one of hydrogen, deuterium, a halogen group, a cyano group, nitro group, a substituted or unsubstituted alkyl group having 1 to 60 carbon atoms, a substituted or unsubstituted haloalkyl group with 1 to 60 carbon atoms, a substituted or unsubstituted haloalkoxy group with 1 to 60 carbon atoms, a substituted or unsubstituted cycloalkyl group with 3 to 60 carbon atoms, a substituted or unsubstituted alkenyl group having 2 to 60 carbon atoms, a substituted or unsubstituted aryl group having 6 to 60 carbon atoms, and a substituted or unsubstituted heterocyclic group having 2 to 60 carbon atoms; and values of c, d, e and f are independently any one of 0, 1, 2 and 3.

It will be understood by those skilled in the art that, L1 to L3, Ar3, Ar4 and R1 to R4 each independently represent a group, c represents a number of groups R1 in the aromatic amine compounds, d represents a number of groups R2 in the aromatic amine compounds, e represents a number of groups R3 in the aromatic amine compounds, and f represents a number of groups R4 in the aromatic amine compounds.

As described above, by adjusting and controlling the hole mobility of the p-type material and the electron mobility of the n-type material, for example, making the two meet a certain proportional relationship, the position of the exciton recombination region in the light-emitting layer EML may be controlled. A ratio of the hole mobility of the p-type material to the electron mobility of the n-type material may be determined depending to actual needs, which is not limited in embodiments of the present disclosure.

In some embodiments, a ratio of the hole mobility of the p-type material to the electron mobility of the n-type material is greater than or equal to 1:100, and less than or equal to 100:1.

It will be easily understood that, the hole mobility is a physical quantity used to characterize a mobility of holes as carriers. A large hole mobility indicates that the holes as carriers move fast; and a small hole mobility indicates that the holes as carriers move slowly. The electron mobility is a physical quantity used to characterize a mobility of electrons as carriers. A large electron mobility indicates that the electrons move fast; and a small electron mobility indicates that the electrons move slowly. In a case where other conditions are same, and the ratio of the hole mobility of the p-type material to the electron mobility of the n-type material is greater than or equal to 1:100 and less than or equal to 100:1, the mobilities of the holes and the electrons as two kinds of carriers in the light-emitting layer EBL are slightly different from each other. Therefore, it is beneficial for the exciton recombination region to be located at a substantial middle position of the light-emitting layer EML in a direction from the anode to the cathode, which improves light-emitting efficiency of the light-emitting layer EML, and light-emitting efficiency of the light-emitting device 2, and prolongs a service life of the light-emitting device 2.

The ratio of the hole mobility of the p-type material to the electron mobility of the n-type material may be determined within the above ratio range depending on actual needs. For example, the ratio of the hole mobility of the p-type material to the electron mobility of the n-type material is equal to 1:100, 50:50 or 100:1.

In some embodiments, the hole mobility of the p-type material is greater than or equal to 1×10⁻⁸ cm²/(V·s), and less than or equal to 1×10⁻⁴ cm²/(V·s). The electron mobility of the n-type material is greater than or equal to 1×10⁻⁸ cm²/(V·s), and less than or equal to 1×10⁻⁴ cm²/(V·s).

As described above, the position of the exciton recombination region in the light-emitting layer EML may also be controlled by adjusting the ratio of the p-type material to the n-type material in the host material. The ratio may be a molar ratio, a mass ratio or the like.

In some embodiments, a molar ratio of the p-type material to the n-type material is greater than or equal to 2:8, and less than or equal to 8:2.

In a case where other conditions are same, and the molar ratio of the p-type material to the n-type material satisfies the proportional relationship, the exciton recombination region may be adjusted to the middle position of the light-emitting layer EML, which is beneficial to further improve performances, such as the light-emitting efficiency and the service life, of the light-emitting device 2.

The molar ratio of the hole mobility of the p-type material to the n-type material may be determined within the above ratio range according to actual needs. For example, the molar ratio of the hole mobility of the p-type material to the n-type material is 2:8, 5:4 or 8:2.

In some embodiments, an absolute value of an energy of a lowest unoccupied molecular orbital (LUMO) of the n-type material is greater than or equal to 2.6 eV, and less than or equal to 3.0 eV; and an absolute value of an energy of a highest occupied molecular orbital (HOMO) of the n-type material is greater than or equal to 5.5 eV, and less than or equal to 6.1 eV.

In some embodiments, an absolute value of an energy of a HOMO of the p-type material is greater than or equal to 5.4 eV, and less than or equal to 5.9 eV; and an absolute value of an energy of a LUMO of the p-type material is greater than or equal to 2.3 eV, and less than or equal to 2.8 eV.

A structure of the n-type material may vary, which are not limited in embodiments of the present disclosure.

In order to clearly illustrate the light-emitting layer EML of the light-emitting device 2 provided in the embodiments of the present disclosure, the following description is made based on simulation experiments performed by the inventors.

A total of 6 groups of simulation experiments are carried out by the inventors. All of light-emitting devices in the 6 groups of simulation experiments adopt the structure shown in FIG. 4. That is, each light-emitting device includes an anode, a hole injection layer HIL, a hole transport layer HTL, an electron blocking layer EBL, a light-emitting layer EML, a hole blocking layer HBL, an electron transport layer ETL and an electron injection layer EIL and a cathode. A thickness of each light-emitting layer is 35 nm. The light-emitting devices in the 6 groups are different from each other only in composition of the host material of the light-emitting layer.

With reference to Table 1 below, for ease of description, the 6 groups of simulation experiments are respectively named as Comparison Group, Group I, Group II, Group III, Group IV and Group V.

A light-emitting layer of a blue light-emitting device in Comparison Group adopts a single host material, and a structural formula of the host material is as shown in the following formula (1-1).

Light-emitting layers of light-emitting devices in Groups I, II, III, IV and V each adopt double host materials.

TABLE 1

| | | | Molar ratio of the |
|---|---|---|---|
| | | | p-type material to |
| Group | p-type material | n-type material | the n-type material |
| Comparison | / | Formula (1-1) | 0:10 |
| Group | | | |
| Group I | Formula (2-1) | Formula (1-1) | 2:8 |
| Group II | Formula (2-1) | Formula (1-1) | 5:5 |
| Group III | Formula (2-1) | Formula (1-1) | 8:2 |
| Group IV | Formula (2-2) | Formula (1-2) | 5:5 |
| Group V | Formula (2-3) | Formula (1-3) | 5:5 |

In double host materials adopted in Groups I, II and III, n-type materials all have a structural formula as shown in the following formula (1-1), and p-type materials all have a structural formula as shown in the following formula (2-1). With reference to Table 1 above, a molar ratio of the p-type material to the n-type material of the light-emitting layer in Group I is 2:8; a molar ratio of the p-type material to the n-type material of the light-emitting layer in Group II is 5:5; and a molar ratio of the p-type material to the n-type material of the light-emitting layer in Group III is 8:2.

In a double host material adopted in Group IV, an n-type material has a structural formula as shown in the following formula (1-2), a p-type material has a structural formula as shown in the following formula (2-2), and a molar ration of the p-type material to the n-type material is 5:5.

In a double host material adopted in Group V, an n-type material has a structural formula as shown in the following formula (1-3), a p-type material has a structural formula as shown in the following formula (2-3), and a molar ration of the p-type material to the n-type material is 5:5.

For each of the light-emitting layers in the 6 groups, a guest material has a structural formula as shown in the following formula (3-1). The 6 groups of host materials are separately doped with the guest material according to a doping ratio of 0.3% by the inventors, so that the light-emitting devices in the 6 groups are finally formed. Here, the doping ratio may be understood as a volume ratio. For example, a host material and the guest material are simultaneously evaporated onto a substrate, on which a light-emitting device is to be formed, by an evaporation process. In the process, an evaporation rate of the guest material is controlled to be 0.3% of an evaporation rate of the host material. In this way, the light-emitting device whose light-emitting layer has the doping ratio of 0.3% is obtained.

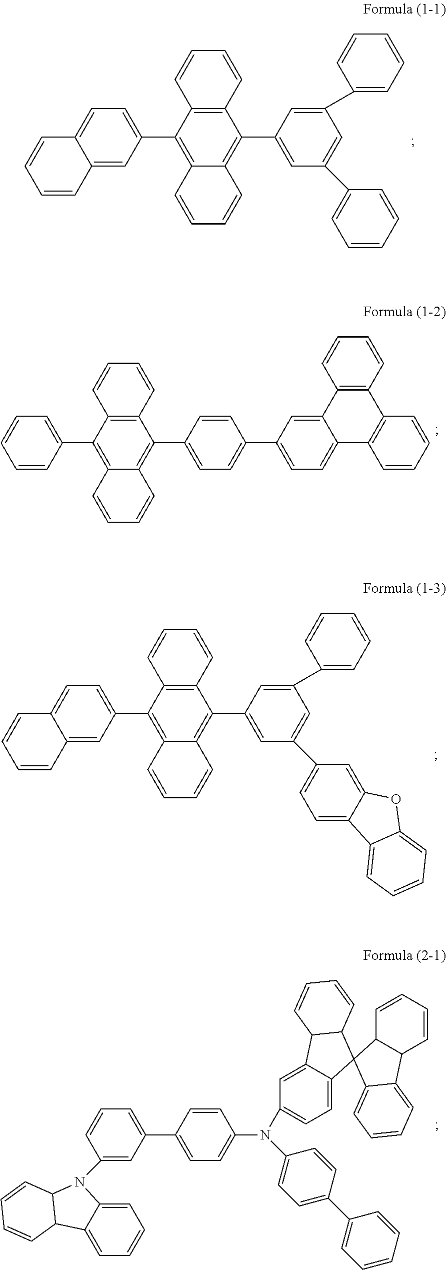

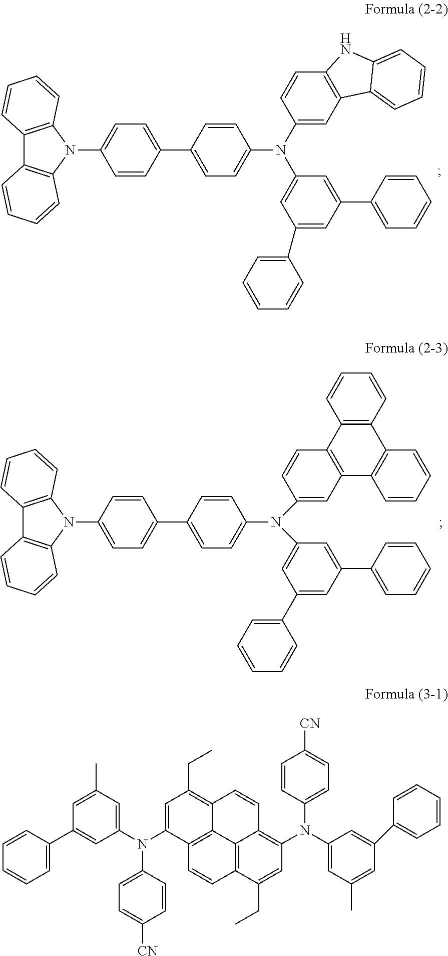 [SMILES: c1ccc(-c2cc(-c3ccccc3)cc(N(c3ccc(-c4ccc(-n5c6ccccc6c6ccccc65)cc4)cc3)c3ccc4[nH]c5ccccc5c4c3)c2)cc1 ; c1ccc(-c2cc(-c3ccccc3)cc(N(c3ccc(-c4ccc(-n5c6ccccc6c6ccccc65)cc4)cc3)c3ccc4c5ccccc5c5ccccc5c4c3)c2)cc1 ; CCc1cc(N(c2ccc(C#N)cc2)c2cc(C)cc(-c3ccccc3)c2)c2ccc3c(CC)cc(N(c4ccc(C#N)cc4)c4cc(C)cc(-c5ccccc5)c4)c4ccc1c2c34]

Table 2 below is a table showing related physical properties of the n-type materials and the p-type materials involved in these examples, where |HOMO| represents an absolute value of an energy of a HOMO, |LUMO| represents an absolute value of an energy of a LUMO, μe represents an electron mobility, and μh represents a hole mobility.

TABLE 2

| | \| HOMO | \| LUMO | Mobility/cm² | |
|---|---|---|---|---|
| | \|/eV | \|/eV | V⁻¹ S⁻¹ | μh/μe |
| n-type | 5.88 | 2.96 | μe = 4.5 × 10⁻⁷ | about |
| material having | | | | 10:1 |
| formula (1-1) | | | | |
| p-type | 5.56 | 2.58 | μh = 2.2 × 10⁻⁶ | |
| material having | | | | |
| formula (2-1) | | | | |
| n-type | 5.82 | 2.90 | μe = 6.8 × 10⁻⁷ | about |
| material having | | | | 100:1 |
| formula (1-2) | | | | |
| p-type | 5.64 | 2.42 | μh = 5.4 × 10⁻⁵ | |
| material having | | | | |
| formula (2-2) | | | | |
| n-type | 5.90 | 3.02 | μe = 3.5 × 10⁻⁵ | about |
| material having | | | | 1:100 |
| formula (1-3) | | | | |
| p-type | 5.62 | 2.46 | μh = 4.9 × 10⁻⁷ | |
| material having | | | | |
| formula (2-3) | | | | |

Based on the light-emitting devices formed by using the respective host materials and the guest material, subsequent effect tests are carried out by the inventors.

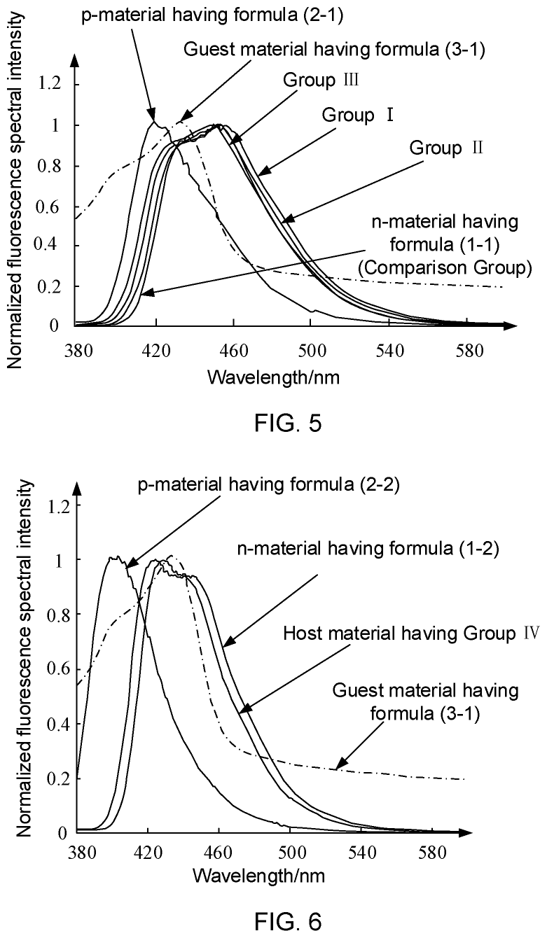

FIG. 5 shows normalized fluorescence spectra, which are obtained through the inventors' tests, of the n-type material shown in formula (1-1), the p-type material shown in formula (2-1), the guest material shown in formula (3-1) and the host materials in Groups I to III. The following conclusions may be drawn from this figure.

Firstly, the normalized fluorescence emission spectra of the host materials in Groups I to III overlap well with the normalized fluorescence emission spectrum of the n-type material shown in formula (1-1), and an absolute value of a difference between a wavelength corresponding to a peak of a normalized fluorescence emission spectrum of any one of the host materials in Groups I to III and a wavelength corresponding to a peak of the normalized fluorescence emission spectrum of the n-type material shown in formula (1-1) is less than 5 nm.

Secondly, the normalized fluorescence emission spectra of the host materials in Groups I to III overlap with the normalized fluorescence absorption spectra of the guest material to a great extent as well.

The above two results indicate that, exciplexes formed by the double host materials in Groups I to III under excitation conditions may fully transfer energy of excitons therein to the guest material like the n-type material in the double host materials, so that light may be emitted.

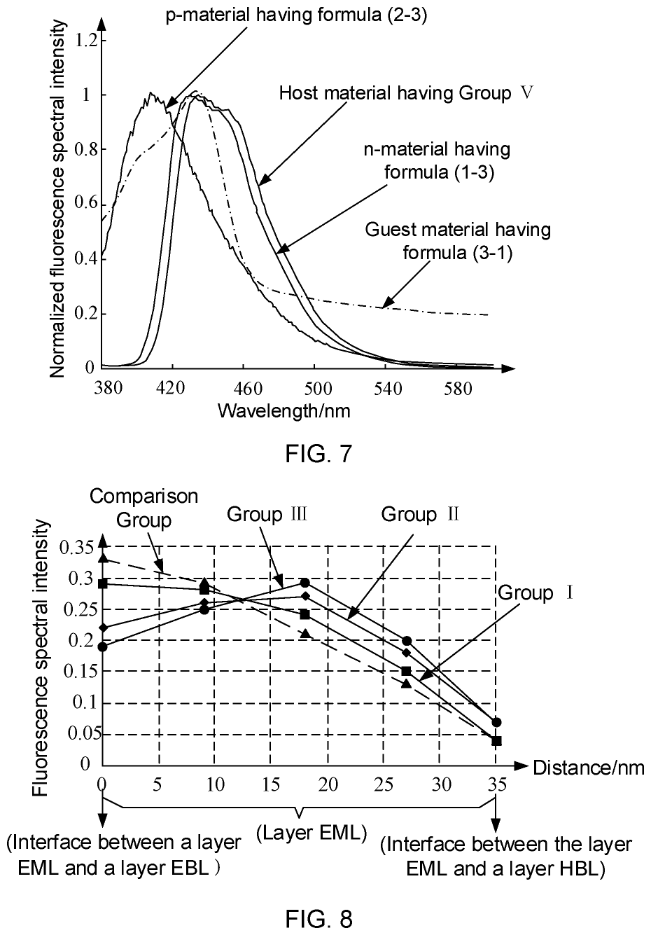

FIG. 6 shows normalized fluorescence spectra, which are obtained through the inventors' tests, of the n-type material shown in formula (1-2), the p-type material shown in formula (2-2), the guest material shown in formula (3-1) and the host material in Group IV. FIG. 7 shows normalized fluorescence spectra, which are obtained through the inventors' tests, of the n-type material shown in formula (1-3), the p-type material shown in formula (2-3), the guest material shown in formula (3-1) and the host material in Group V. It will easily understood that, according to FIGS. 6 and 7, exciplexes formed by the double host materials in Groups IV and V under excitation conditions may also fully transfer energy of excitons therein to the guest material, so that light may be emitted. Specific analysis therefor is similar to the analysis for FIG. 5, which will not be repeated here.

FIG. 8 is a graph showing distribution curves of fluorescence spectral intensity versus distance for the light-emitting devices in Comparison Group and Groups I to III. It will be easily understood that, for such curves, a position where there is a larger fluorescence spectral intensity indicates that there are more excitons combining with each other at this position. Clearly, the following conclusions may be drawn from FIG. 8.

Firstly, for a curve corresponding to Comparison Group, a spectral intensity gradually decreases in a direction from left to right along the abscissa. This indicates that most excitons recombine at and near an interface between a light-emitting layer EML and an electron blocking layer EBL, which results in low light-emitting efficiency and a short service life of the light-emitting device in Comparison Group.

Secondly, compared with the curve of Comparison Group, for a curve corresponding to any one of Groups I to III, a peak thereof occurs at a position about 18 nm from an interface between a light-emitting layer EML and an electron blocking layer EBL, i.e., near a middle position of the light-emitting layer EML, and a trend of the curve is relatively gentle. This indicates that most excitons in the light-emitting devices in Groups I to III recombine at middle positions of the light-emitting layers EML, and the exciton recombination regions each are distributed more evenly than an exciton recombination region in light-emitting device in Comparison Group. Therefore, the light-emitting devices in Groups I to III have better performances such as higher light-emitting efficiency and a longer service life.

Thirdly, among Groups I to III, most excitons in the light-emitting device in Group II recombine at the middle position of the light-emitting layer EML, and the exciton recombination region is most evenly distributed. This indicates that, in conjunction with Table 1 and FIG. 8, a change in molar ratio of two host materials of the double host material, i.e., the change in the molar ratio of the p-type material shown in formula (2-1) and the n-type material shown in formula (1-1) causes a change in position of the exciton recombination region. In addition, in a case where the molar ratio of the p-type material shown in formula (2-1) to the n-type material shown in formula (1-1) is 5:5, the exciton recombination region may be closer to the middle position of the light-emitting layer EML and be more evenly distributed. The solution corresponding to Group III is relatively conducive to improving the performances, such as the light-emitting efficiency and the service life, of the light-emitting device.

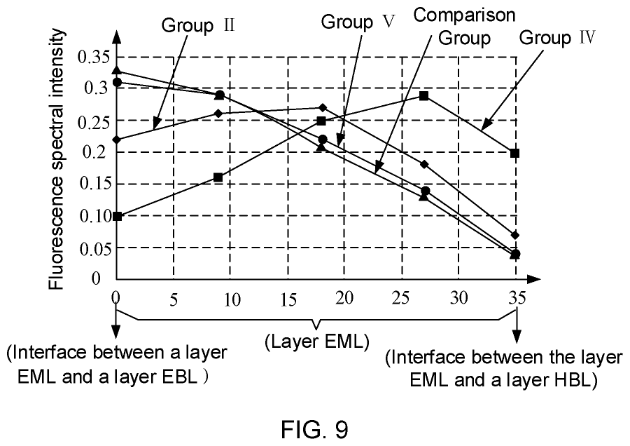

FIG. 9 is a graph showing distribution curves of electroluminescence spectral intensity versus distance for the light-emitting devices in Comparison Group and Groups II, IV and V. The following conclusions may be drawn from FIG. 9.

Firstly, peaks of curves corresponding to Groups II and IV both occur at a side, closer to the middle position of the light-emitting layer EML, than a peak of a curve corresponding to Comparison Group. This indicates that most excitons in light-emitting devices in Group II and IV recombine near middle positions of respective light-emitting layers EML. Although a peak of a curve corresponding to Group V occurs at an interface between an electron blocking layer EBL and a light-emitting layer EML like the peak of the curve corresponding to Comparison Group, a value of the peak of the curve corresponding to Group V is less than a value of the peak of the curve corresponding to Comparison Group, and a trend of the curve of Group V is more gentle. This indicates that, compared with an exciton recombination region of Comparison Group, an exciton recombination region corresponding to Group V is closer to the middle position of the light-emitting layer EML. It may be seen that, the double host material in Group II, the double host material in Group IV and the double host material in Group V may all make the exciton recombination region proximate to the middle position of the light-emitting layer EML, which is conducive to improving the performances, such as the light-emitting efficiency and the service life, of the light-emitting device.

Secondly, among Groups II, IV and V, in conjunction with Tables 1 to 2 and FIG. 9, the peak of the curve corresponding to Group II (where the ratio of hole mobility of p-type material to the electron mobility of the n-type material is 10:1) occurs at a position closest to the middle position of the light-emitting layer EML, a peak of a curve corresponding to Group IV (where a ratio of the hole mobility of the p-type material to the electron mobility of the n-type material is 100:1) occurs at a position closer to the hole blocking layer HBL compared with the peak of the curve corresponding to Group II, and the peak of the curve corresponding to Group V (where the ratio of the hole mobility of the p-type material to the electron mobility of the n-type material is 1:100) occurs at a position closer to the electron blocking layer EBL compared with the peak of the curve corresponding to Group II.

It may be seen that, in a case where other conditions are same, as the ratio of the hole mobility of the p-type material to the electron mobility of the n-type material in the double host material becomes larger, the exciton recombination region is likely to move towards a side of the light-emitting layer EML proximate to the hole blocking layer HBL; otherwise, in a case where other conditions are the same, as the ratio of the hole mobility of the p-type material to the electron mobility of the n-type material in the double host material becomes smaller, the exciton recombination region is likely to move towards a side of the light-emitting layer EML proximate to the electron blocking layer EBL. It will be easily understood that, in a case where other conditions are the same, generally, the closer the hole mobility of the p-type material in the double host material is to the electron mobility of the n-type material in the double host material, the closer the exciton recombination region in the light-emitting layer EML to the middle position of the light-emitting layer EML. In this case, the light-emitting device has better light-emitting efficiency and longer service life.

Therefore, under other conditions are the same, by adjusting the relative ratio of the hole mobility of the p-type material to the electron mobility of the n-type material in the double host material depending on actual needs, it may be possible to adjust a position of the exciton recombination region in the light-emitting layer EML.

Table 3 below shows current-voltage-luminance (IVL) data of the light-emitting devices in Comparison Group and Groups I to V under a condition where the light-emitting devices are each driven to emit light of a color with CIEx of 0.142 (CIEx=0.142) and CIEy of 0.045 (CIEy=0.045). Here, CIEx represents an abscissa value of a color coordinate of light emitted by a light-emitting device, CIEy represents an ordinate value of the color coordinate of the light emitted by the light-emitting device, U represents a voltage value between an anode and a cathode when a density of a current flowing through the light-emitting device is 15 mA/cm², Cd represents a luminance, A represents a value of the flowing current, Cd/A/CIEy represents a chrominance efficiency as a whole, LT95 represents a time for the luminance of the light-emitting device to decay to 95% of an initial luminance when the light-emitting device is continuously lit.

TABLE 3

| Group | CIEx | CIEy | U/V | Cd/A/CIEy | LT95/h |
|---|---|---|---|---|---|
| Comparison | 0.142 | 0.045 | 4.3 | 102 | 116 |
| Group | | | | | |
| Group I | | | 3.9 | 171 | 168 |
| Group II | | | 3.9 | 175 | 180 |
| Group III | | | 3.9 | 172 | 196 |
| Group IV | | | 4.1 | 126 | 122 |
| Group V | | | 4.2 | 135 | 131 |

Those skilled in the art should understand that, (1) in a case where CIEx and CIEy of light emitted by the light-emitting device are fixed, the color of the light emitted by the light-emitting device is determined; (2) generally, in a single pixel including a light-emitting device for emitting red light, a light-emitting device for emitting green light and a light-emitting device for emitting blue light, values of U of the light-emitting device for emitting red light and the light-emitting device for emitting green light are relatively close to each other, so a single voltage terminal may be used to supply driving voltages to the two; and a value of U of the light-emitting device for emitting blue light is usually greater than the values of U of the light-emitting device for emitting red light and the light-emitting device for emitting green light, so an additional voltage terminal is needed to supply a driving voltage to the light-emitting device for emitting blue light; (3) a larger value of Cd/A/CIEy indicates a higher light-emitting efficiency of a corresponding light-emitting device; and (4) a larger value of LT95 indicates a longer service life of the light-emitting device.

The following conclusions may be drawn from Table 3.

Firstly, compared with a value of U corresponding to Comparison Group, values of U corresponding to Groups I to V are all smaller, which indicates that the light-emitting devices 2 adopting the double host material in the embodiments of the present disclosure are more likely to have the same diving voltage as a light-emitting device for emitting red light and a light-emitting device for emitting green light. Therefore, in a case where the light-emitting device 2 provided in the embodiments of the present disclosure serves as a light-emitting device for emitting blue light, it may be conductive to using a single voltage terminal to supply voltages for the light-emitting device for emitting red light, the green light-emitting device for emitting green light and the light-emitting device for emitting blue light, thereby reducing a number of voltage terminals required in the light-emitting apparatus and power consumption.

Secondly, compared with a value of Cd/A/CIEy corresponding to Comparison Group, values of Cd/A/CIEy corresponding to Groups I to V are greater, which indicates that the light-emitting devices adopting the double host material in the embodiments of the present disclosure have higher light-emitting efficiency than a light-emitting device in the related art.

Thirdly, compared with a value of LT95 corresponding to Comparison Group, values of LT95 corresponding to Groups I to V are greater, which indicates that the light-emitting devices adopting the double host material in the embodiments of the present disclosure has longer service life than the light-emitting device in the related art.

Fourth, in conjunction with the values of U, Cd/A/CIEy and LT95 corresponding to Groups I to V, the light-emitting device in Group II has relatively good performances, such as a light-emitting driving voltage closer to the driving voltages of the light-emitting device for emitting red light and the light-emitting device for emitting green light, a higher light-emitting efficiency and a longer service life.

The above embodiments are only used to illustrate but not to limit the technical solutions of the present disclosure. Although the present disclosure is described in detail with reference to the foregoing embodiments, those skilled in the art shall understand that: a person stilled in the art is still able to modify the technical solutions recorded in the foregoing embodiments, or to make equivalent substitutions for some of the technical features thereof; and such modifications or substitutions do not depart the essence of the corresponding technical solutions from the spirit and scope of the technical solutions of the embodiments of the present disclosure.

1. A light-emitting device, comprising: a light-emitting layer, the light-emitting layer including a host material, the host material including:
a p-type material and an n-type material, the p-type material and the n-type material being configured to form an exciplex, an absolute value of a difference between a wavelength corresponding to a peak of a normalized fluorescence emission spectrum of the exciplex and a wavelength corresponding to a peak of a normalized fluorescence emission spectrum of the n-type material being less than or equal to 5 nm.

2. The light-emitting device according to claim 1, wherein
a difference between an energy of singlet excitons of the exciplex and an energy of triplet excitons of the exciplex is less than or equal to 0.3 eV.

3. The light-emitting device according to claim 1, wherein
a ratio of a hole mobility of the p-type material to an electron mobility of the n-type material is greater than or equal to 1:100, and less than or equal to 100:1.

4. The light-emitting device according to claim 3, wherein
the hole mobility of the p-type material is greater than or equal to 1×10⁻⁸ cm²/(V·s), and less than or equal to 1×10⁻⁴ cm²/(V·s), and
the electron mobility of the n-type material is greater than or equal to 1×10⁻⁸ cm²/(V·s), and less than or equal to 1×10⁻⁴ cm²/(V·s).

5. The light-emitting device according to claim 1, wherein
the wavelength corresponding to the peak of the normalized fluorescence emission spectrum of the n-type material is greater than or equal to 430 nm, and less than or equal to 470 nm.

6. The light-emitting device according to claim 1, wherein
a wavelength corresponding to a peak of a normalized fluorescence emission spectrum of the p-type material is greater than or equal to 380 nm, and less than or equal to 430 nm.

7. The light-emitting device according to claim 1, wherein
an absolute value of an energy of a lowest unoccupied molecular orbital of the n-type material is greater than or equal to 2.6 eV, and less than or equal to 3.0 eV; and
an absolute value of an energy of a highest occupied molecular orbital of the n-type material is greater than or equal to 5.5 eV, and less than or equal to 6.1 eV.

8. The light-emitting device according to claim 1, wherein
an absolute value of an energy of a highest occupied molecular orbital of the p-type material is greater than or equal to 5.4 eV, and less than or equal to 5.9 eV; and
an absolute value of an energy of a lowest unoccupied molecular orbital of the p-type material is greater than or equal to 2.3 eV, and less than or equal to 2.8 eV.

9. The light-emitting device according to claim 1, wherein
a mole ratio of the p-type material to the n-type material is greater than or equal to 2:8, and less than or equal to 8:2.

10. The light-emitting device according to claim 1, wherein
the n-type material is selected from anthracene compounds.

11. The light-emitting device according to claim 10, wherein
a general formula of the anthracene compounds is: 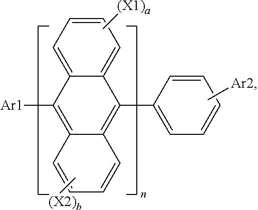
wherein Ar1 represents any one of phenyl group, naphthyl group and biphenyl group; Ar2 represents any one of phenyl group, 1-naphthyl group, 2-naphthyl group, 2-biphenyl group, 3-biphenyl group and 4-biphenyl group; X1 and X2 each independently represent any one of an aryl group having 6 to 50 ring carbon atoms, an aromatic heterocyclic group having 5 to 50 ring atoms, an alkyl group having 1 to 50 carbon atoms, an alkoxy group having 1 to 50 carbon atoms, an aralkyl group having 6 to 50 carbon atoms, an aryloxy group having 5 to 50 ring atoms, an arylthio group having 5 to 50 ring atoms, an alkoxycarbonyl group having 1 to 50 carbon atoms, a carboxyl group, halogen, a cyano group, a nitro group and a hydroxyl group; a value of n is any one of 1, 2 and 3; and values of a and b each are independently any one of 0, 1, 2 and 3.

12. The light-emitting device according to claim 1, wherein
the p-type material is selected from aromatic amine compounds.

13. The light-emitting device according to claim 12, wherein
a general formula of the aromatic amine compounds is: 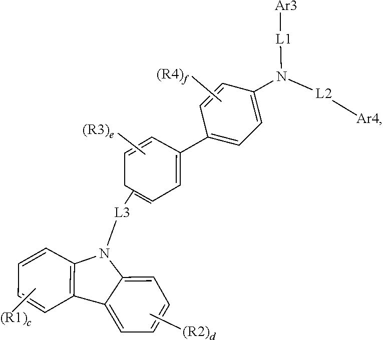
wherein L1 to L3 each independently represent a direct bonding, or a substituted or unsubstituted arylene group with 6 to 60 carbon atoms; Ar3 and Ar4 each independently represent any one of hydrogen, deuterium, halogen, a cyano group, a nitro group, a substituted or unsubstituted silyl group, a substituted or unsubstituted alkyl group, a substituted or unsubstituted cycloalkyl group, a substituted or unsubstituted aryl group having 6 to 60 carbon atoms, and a substituted or unsubstituted heterocyclic group having 2 to 60 carbon atoms; R1 to R4 each independently represent any one of hydrogen, deuterium, halogen, a cyano group, nitro group, a substituted or unsubstituted alkyl group having 1 to 60 carbon atoms, a substituted or unsubstituted haloalkyl group with 1 to 60 carbon atoms, a substituted or unsubstituted haloalkoxy group with 1 to 60 carbon atoms, a substituted or unsubstituted cycloalkyl group with 3 to 60 carbon atoms, a substituted or unsubstituted alkenyl group having 2 to 60 carbon atoms, a substituted or unsubstituted aryl group having 6 to 60 carbon atoms, and a substituted or unsubstituted heterocyclic group having 2 to 60 carbon atoms; and values of c, d, e and f each are independently any one of 0, 1, 2 and 3.

14. A light-emitting substrate, comprising a base substrate and a plurality of light-emitting devices disposed on the base substrate, wherein
at least one of the plurality of light-emitting devices is the light-emitting device according to claim 1.

15. A light-emitting apparatus, comprising the light-emitting substrate according to claim 14.

16. The light-emitting device according to claim 1, further comprising:
a first electrode and a second electrode that are disposed opposite to each other, the light-emitting layer being located between the first electrode and the second electrode.

17. The light-emitting device according to claim 16, further comprising: a hole injection layer, a hole transport layer, an electron blocking layer, a hole blocking layer, an electron transport layer and an electron injection layer, wherein
the hole injection layer, the hole transport layer and the electron blocking layer are located between the first electrode and the light-emitting layer; and the hole blocking layer, the electron transport layer and the electron injection layer are located between the light-emitting layer and the second electrode.

18. The light-emitting device according to claim 3, wherein the ratio of the hole mobility of the p-type material to the electron mobility of the n-type material is 1:100, 50:50 or 100:1.

19. The light-emitting device according to claim 9, wherein the mole ratio of the p-type material to the n-type material is 2:8, 5:4 or 8:2.
